(19) United States
(12) Patent Application Publication
(10) Pub. No.: US 2004/0194923 A1
(43) Pub. Date: Oct. 7, 2004

(54) Heat sink assembly for facilitating air flow

(75) Inventor: Chin-Yueh Chu, Hsin-Chuang CIty (TW)

Correspondence Address: TROXELL LAW OFFICE PLLC, SUITE 1404, 5205 LEESBURG PIKE, FALLS CHURCH, VA, 22041, US

(73) Assignee: Datech Technology Co., Ltd.

(21) Appl. No.: 10/619,474

(22) Filed: Jul. 16, 2003

(30) Foreign Application Priority Data
Apr. 1, 2003 (TW) 092205130

(51) Int. Cl. H05K 7/20

(52) U.S. Cl. 165/80.3; 165/185

(57) ABSTRACT

The present invention provides a heat sink assembly, including a base portion with a heat dissipation part and a plurality of heat sinks disposed on the base portion. A platform is disposed in one side of the base portion and an inclined plane is respectively disposed in two sides of the platform. The heat sinks are disposed in the direction extending upward from the platform and the inclined plane in the two sides. The heat sinks are lined up with equally spaced distance. Whereby the heat sink assembly guides and facilitates air flow so as to dissipate heat.

### REFERENCE CITED

1. U.S. Pat. No. 6,460,609

2. U.S. Pat. No. 6,446,707

### FIELD OF THE INVENTION

The present invention relates to a heat sink assembly, and more particularly to, a heat sink assembly which can efficiently guide and facilitate air flow so as to dissipate heat.

### BACKGROUND OF THE INVENTION

As the computer technology keeps improving, devices and equipments in the personal computer field also make huge progress: It is obvious that more processing information relating to multi-media and faster processing speed are now available to users. However, the inner operation temperature of personal computer equipments and IC devices become higher. Even the IC in interface cards will generate heat. Therefore, without proper heat dissipation, it can not operate normally and will result in low speed and even reduce its life-span. The conventional heat sink assembly (as shown in FIG. 4) is composed of a base portion 5 and at least one heat sink 51 extending upward from the base portion 5. Moreover, a fan 52 is disposed in the heat sink 51 so that the heat sink 51 can absorb the heat generated by a CPU 6. The fan 52 guides the air flow generated to the heat sink 51 to dissipate heat.

However, since the heat sink assembly is formed by a base portion 5 and at least one heat sink 51, when the fan 52 on the heat sink 51 blows the heat sink 51, the air flow generated by the fan 52 is guided to the heat sink 51 in the edge of the base portion 5 without guiding the air flow to central portion of the base portion 5 due to the original character of the fan 52. (The fan guides air out by its blades along with the axis center 521. Thus, the axis center 521 usually has smaller air flow) But since the central portion of the base portion 5 of the heat sink assembly absorbs directly the heat of the CPU 6, the temperature in the central portion of the base portion of the heat sink assembly is higher. Thus, the fan 52 can not directly guide the air out to the central portion of the base portion 5 of the heat sink assembly due to the axis center 521. Consequently, the conventional heat sink assembly apparently can not achieve the objective to dissipate heat.

Therefore, some relative manufacturers design another heat sink assembly (as shown in FIG. 5) composed of a base portion 7 and more than one heat sink 71 upward extending from the base portion 7. An extension portion 72 is disposed in the central portion of the base portion 7 and on the button of the heat sinks 71. The extension portion 72 is in a triangular shape. A fan 73 is disposed on the heat sink 71 so that the extension portion 72 and the heat sink 71 will absorb the heat of the CPU 6 and the fan 71 guides the air flow to the extension portion 72 and the heat sink 71 for facilitating heat dissipation.

Although the above mentioned heat sink assembly may improve the heat dissipation, the extension portion 72 of the central portion of the base portion 7 of the heat sink assembly is in a triangular shape, so that the air flow will be divided into two parts and directly blow out from the heat sink assembly. The air flow blown from the fan 73 can not stay in the extension portion 72 and the heat sink 71 and will be pulled out directly. This kind of heat sink assembly apparently does not have substantially improvement with comparison to the conventional heat sink assembly. Therefore, the conventional apparatus can not meet users' needs.

### SUMMARY OF THE INVENTION

The main objective of the present invention is to provide a heat sink assembly that can efficiently guide and facilitate air flow so as to dissipate heat.

To achieve the above objective, in the present invention, the heat sink assembly includes a base portion with a heat dissipation part, wherein a platform is disposed in one side of the base portion and an inclined plane is respectively disposed in two sides of the platform; and

a plurality of heat sinks on the base portion, wherein the heat sinks are disposed in the direction extending upward from the platform and the inclined plane in the two sides. The heat sinks are lined up with equally spaced distance.

Whereby the heat sink assembly guides and facilitates air flow so as to dissipate heat.

### BRIEF DESCRIPTION OF THE DRAWINGS

The present invention will be better understood from the following detailed description of preferred embodiments of the invention, taken in conjunction with the accompanying drawings, in which

FIG. 1 is a diagram showing an outward appearance of the present invention;

FIG. 2 is a diagram showing a view in operation configuration of the present invention;

FIG. 3 is a cross-section diagram showing a view in operation configuration of the present invention;

FIG. 4 is a cross-section diagram of the conventional heat sink assembly; and

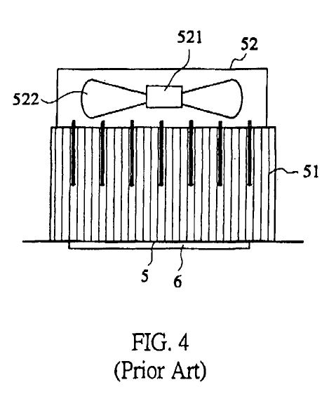

FIG. 5 is another cross-section diagram of the conventional heat sink assembly.

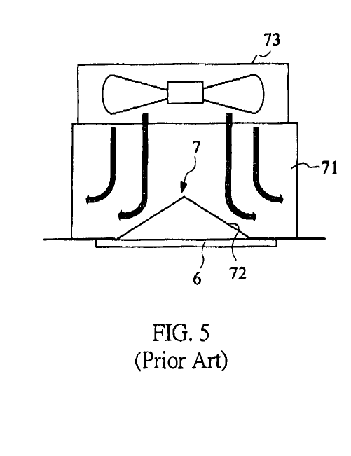

### DETAIL DESCRIPTION OF THE INVENTION

The following descriptions of the preferred embodiments are provided to understand the features and the structures of the present invention.

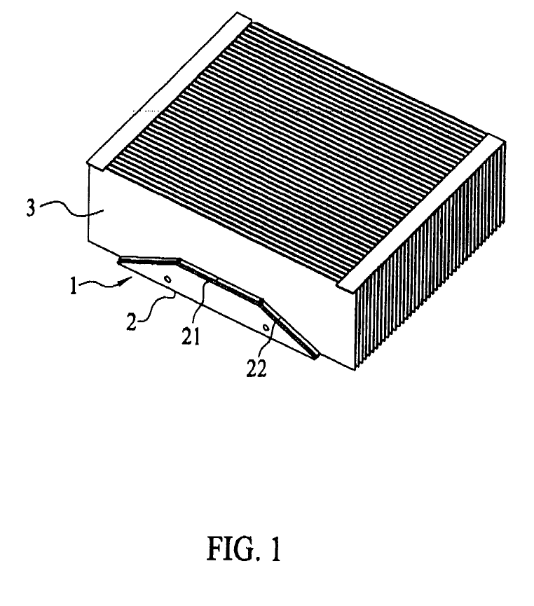

FIG. 1 is a diagram showing an outward appearance of the present invention. As shown in the diagram, the present invention provides a heat sink assembly, including a base portion 1, a heat dissipating part 2, and a plurality of heat sinks 3. By the structure of the present invention, the heat sink assembly guides and facilitates air flow so as to dissipate heat. The base portion 1 can be located in the central portion of the CPU (not shown). The base portion 1 has a heat dissipation part 2. A platform 21 is disposed in one side of the base portion 1 and an inclined plane 22 is respectively disposed in two sides of the platform 21. The heat dissipation part 2 extends from one end of the base portion 1 to another end.

The heat sinks 3 are disposed on the base portion 1. The heat sinks 3 are disposed in the direction extending upward from the platform 21 of the base portion 1 and the inclined plane 22 in the two sides. The heat sinks 3 are lined up with equally spaced distance. The base portion 1 is disposed in the central portion of the heat sinks 3. A frame 4 is disposed out of the heat sinks 3. A fan 41 is disposed on the frame 4. Therefore, a whole new structure of heat sink assembly is provided.

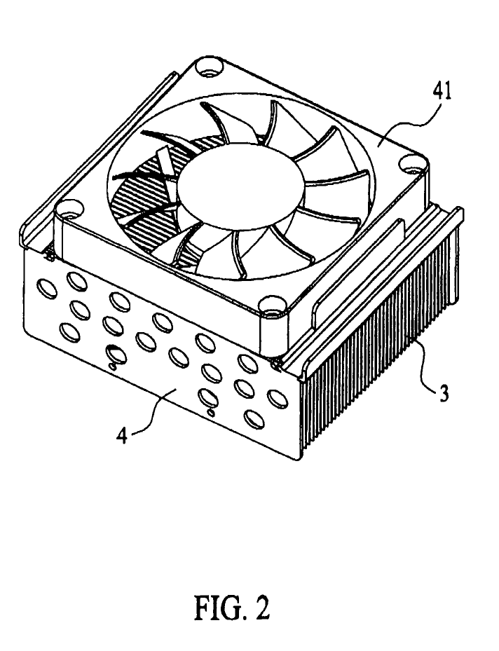

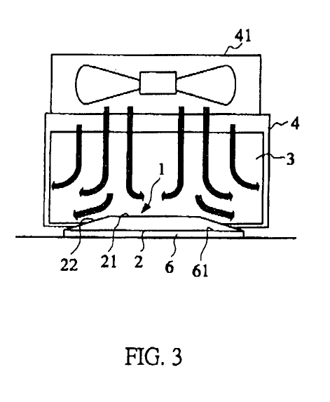

FIG. 2 and FIG. 3 are respectively a diagram showing a view in operation configuration of the present invention and a cross-section diagram showing a view in operation configuration of the present invention. As shown in the diagram, the base portion 1 of the heat sink assembly of the present invention is disposed on CPU 6 when using. The heat dissipation part 2 evenly sticks on the CPU 6 by means of a thermally conductive adhesive 61. When the CPU 6 operates, the base portion 1 starts to absorb the heat generated by the CPU 6. Since the central portion of the heat dissipation part 2 of the base portion 1 evenly sticks on the CPU 6, the heat dissipation part 2 of the base portion 1 directly absorb the heat of the CPU 6. Therefore, the temperature in the central portion of the heat dissipation part 2 is often higher, and will transmit the heat to the heat sinks 3 with lower temperature. (heat always is transmitted from a position with higher temperature to another position with lower temperature) For the time being, be means of the fan 41 disposed on the frame 4, the air flow blown by the fan 41 will be guided to the heat sinks 3 so as to dissipate heat. Moreover, since the base portion 1 has a heat dissipation part 2, the heat generated by the CPU 6 will be absorbed by the heat dissipation part 2 of the base portion 1. When the air flow from the fan 41 blows downward (toward the direction of the heat sinks 3), the air flow will generate a force outer downward due to the heat sinks 3. The air flow will result in interference on the platform 21 in the side of the heat dissipation part 2. Parts of the air flow, which used to blow away from two sides of the heat sinks 3, will be guided to the platform 21 under influence of each other. The air flow results in the interference on the platform 21 and forced by the force and guided out from the inclined plate 22 disposed in two sides of the platform 21. Therefore, by the platform 21 of the heat dissipation part 2 and the inclined plate 22 in two sides of the platform 21, the heat sink assembly guides and facilitates air flow so as to dissipate heat.

The present invention may be embodied in other specific forms without departing from the spirit of the essential attributes thereof; therefore, the illustrated embodiment should be considered in all respects as illustrative and not restrictive, reference being made to the appended claims rather than to the foregoing description to indicate the scope of the invention.

What is claimed is:

1. A heat sink assembly for facilitating air flow, comprising:
a base portion having a heat dissipation part, wherein a platform is disposed in one side of said base portion and an inclined plane is respectively disposed in two sides of said platform; and
a plurality of heat sinks disposed on said base portion, wherein said heat sinks are disposed in the direction extending upward from said platform and said inclined plane in said two sides, said heat sinks are lined up with equally spaced distance;
whereby said heat sink assembly guides and facilitates air flow so as to dissipate heat.

2. The heat sink assembly of claim 1, wherein a frame is disposed out from said heat sinks of said heat sink assembly.

3. The heat sink assembly of claim 2, wherein a fan is disposed on said frame.

4. The heat sink assembly of claim 1, wherein said heat dissipation part extends from one end of said base portion to another end.

5. The heat sink assembly of claim 1, wherein said base portion is disposed in the central portion of said heat sinks.
